(19) United States
(12) Patent Application Publication
(10) Pub. No.: US 2015/0083183 A1
(43) Pub. Date: Mar. 26, 2015

(54) SOLAR CELL, MANUFACTURING METHOD FOR SOLAR CELL, AND SOLAR CELL MODULE

(71) Applicant: Yoichiro Nishimoto, Chiyoda-ku (JP)

(72) Inventor: Yoichiro Nishimoto, Chiyoda-ku (JP)

(73) Assignee: Mitsubishi Electric Corporation, Chiyoda-ku (JP)

(21) Appl. No.: 14/394,367

(22) PCT Filed: Apr. 25, 2012
(86) PCT No.: PCT/JP2012/061106

§ 371 Date: Oct. 14, 2014

(51) Int. Cl. H01L 31/18; H01L 31/065; H01L 31/0236; H01L 31/0216

(52) U.S. Cl. CPC H01L 31/1868; H01L 31/02168; H01L 31/065; H01L 31/1864; H01L 31/02366
USPC 136/244; 136/256; 438/87

(57) ABSTRACT

A solar cell includes: a semiconductor substrate of a first conductivity type that includes an impurity diffusion layer, in which an impurity element of a second conductivity type is diffused, on one surface side; a passivation film that is formed on the impurity diffusion layer and that is made of an oxide film of a material of the semiconductor substrate; an anti-reflective film that is made of a translucent material having a refractive index different from that of the oxide film and that is formed on the passivation film; a light-receiving-surface-side electrode that is electrically connected to the impurity diffusion layer and that is formed on one surface side of the semiconductor substrate; and a rear-surface-side electrode that is formed on another surface side of the semiconductor substrate.

### FIELD

The present invention relates to a solar cell, a manufacturing method for a solar cell, and a solar cell module.

### BACKGROUND

It is necessary to suppress recombination of carriers to increase efficiency of a solar cell. As one method for suppressing recombination, there is a Selective Emitter (hereinafter referred to as SE) structure. The structure of a general crystalline silicon (Si) solar cell is a structure in which an anti-reflective film is formed on a photoelectric conversion section in which a p-n junction is formed, a comb-shaped electrode is arranged on the front surface (a light receiving surface), and a full-surface electrode is arranged on the rear surface. Such a solar cell is called Homogeneous Emitter cell (hereinafter referred to as HE cell).

Because of the characteristics of a solar cell, the impurity concentration in the outermost surface of a light receiving region (an interface between an anti-reflective film and an impurity layer on a light receiving surface side) affects recombination of carriers. For example, it is known that, when the impurity density in the outermost surface of the light receiving region increases, recombination of carriers increases and the characteristics of the solar cell are deteriorated. Therefore, for the purpose of suppressing recombination of carriers, a method of etching the outermost surface of a semiconductor substrate to reduce the impurity concentration is reported (see, for example, Non Patent Literature 1).

However, in the above method, the impurity concentration in a region corresponding to a region under an electrode on the light receiving surface side (an electrode forming region) also decreases. In general, the ohmic characteristics of an electrode are better when the impurity concentration under the electrode is higher. This is contrary to a condition suitable for the suppression of recombination of carriers.

Therefore, the SE structure is devised. The SE structure is a structure in which impurity diffusion layers of two specifications are provided in a plane on a light receiving surface side of a semiconductor substrate, that is, on a light receiving surface side of the semiconductor substrate, a light receiving region is a low-concentration diffusion layer, in which the impurity concentration is set low to suppress recombination of carriers, and, on the other hand, a region corresponding to a region under an electrode on the light receiving surface side (an electrode forming region) is a high-concentration diffusion layer, in which the impurity concentration is set high. In a cell using the SE structure in the past (hereinafter referred to as SE cell), a texture is formed in the light receiving region on the light receiving surface side of the semiconductor substrate. The electrode forming region where a light-receiving-surface-side electrode is formed later is formed in a flat state or is grooved. In this way, the high-concentration diffusion layer and the low-concentration diffusion layer are distinguished according to the surface shapes (see, for example, Non Patent Literature 1 and Non Patent Literature 2). However, the method of locally changing the surface shape on the light receiving surface side of the semiconductor substrate is not considered to be a method suitable for mass production because a process is complicated.

Therefore, as a simple method of forming the SE structure, there is proposed a method of selectively forming the high-concentration diffusion layer by locally heating, with a laser, the electrode forming region where the light-receiving-surface-side electrode is formed after the low-concentration diffusion layer is formed by thermal diffusion on the light receiving surface side of the semiconductor substrate (see, for example, Non Patent Literatures 2 and 3).

### CITATION LIST

### Patent Literature

Non Patent Literature 1: J. Lindmayer & J. Allison “AN IMPROVED SILICON SOLAR CELL-THE VIOLET CELL” IEEE Photovoltaic Specialists Conference 9th p. 83
Non Patent Literature 2: J. Zhao, A. Wang, X. Dai, M. A. Green and S. R. Wenham, “IMPROVEMENT IN SILICON SOLAR CELL PERFORMANCE”, Proceedings of 22nd IEEE Photovoltaic Specialists Conference, 1991, p 399
Non Patent Literature 3: T. Fries, A. Teppe, J. Olkowska-Oetzel, W. Zimmermann, C. Voyer, A. Esturo-Breton, J. Isenberg, S. Keller, D. Hammer, M. Schmidt and P. Fath, “SELECTIVE EMITTER ON CRYSTALLINE SI SOLAR CELLS FOR INDUSTRIAL HIGH EFFICIENCY MASS PRODUCTION”, Proceedings of 25th European Photovoltaic Solar Energy Conference and Exhibition 5th World Conference on Photovoltaic Energy Conversion, 2010, 2CV3.2-8

### SUMMARY

### Technical Problem

However, according to the conventional technologies, there is no difference between the surface shapes of the light receiving region and the electrode forming region. A light-receiving-surface-side electrode of a general crystal silicon solar cell is formed by printing and baking paste. However, in the conventional technologies, because there is no difference between the surface shapes of the light receiving region and the electrode forming region, there is a problem in that it is extremely difficult to align the printing of the paste.

The present invention has been devised in view of the above and it is an object of the present invention to obtain a solar cell, a manufacturing method for a solar cell, and a solar cell module with a simple electrode formation and excellent photoelectric conversion characteristics.

### Solution to Problem

In order to solve the above problems and achieve the object, a solar cell related to the present invention including: a semiconductor substrate of a first conductivity type that includes an impurity diffusion layer, in which an impurity element of a second conductivity type is diffused, on one surface side; a passivation film that is formed on the impurity diffusion layer and that is made of an oxide film of a material of the semiconductor substrate; an anti-reflective film that is made of a translucent material having a refractive index different from that of the oxide film and that is formed on the passivation film; a light-receiving-surface-side electrode that is electrically connected to the impurity diffusion layer and that is formed on one surface side of the semiconductor substrate; and a rear-surface-side electrode that is formed on another surface side of the semiconductor substrate, wherein the impurity diffusion layer includes a first impurity diffusion layer, which is a light receiving region and contains the impurity element at a first concentration, and a second impurity diffusion layer, which is a lower region of the light-receiving-surface-side electrode and contains the impurity element at a second concentration higher than the first concentration, surfaces of the first impurity diffusion layer and the second impurity diffusion layer are formed in a uniform surface state, and a thickness of the passivation film on the second impurity diffusion layer is smaller than a thickness of the passivation film on the first impurity diffusion layer.

### Advantageous Effects of Invention

According to the present invention, an effect is obtained where it is possible to obtain a solar cell with a simple electrode formation and excellent photoelectric conversion characteristics.

### BRIEF DESCRIPTION OF DRAWINGS

FIG. 1 is a flowchart for explaining an example of a manufacturing process for a solar cell according to a first embodiment of the present invention.

FIG. 2-1 is a main part sectional view for explaining the example of the manufacturing process for the solar cell according to the first embodiment of the present invention.

FIG. 2-2 is a main part sectional view for explaining the example of the manufacturing process for the solar cell according to the first embodiment of the present invention.

FIG. 2-3 is a main part sectional view for explaining the example of the manufacturing process for the solar cell according to the first embodiment of the present invention.

FIG. 2-4 is a main part sectional view for explaining the example of the manufacturing process for the solar cell according to the first embodiment of the present invention.

FIG. 2-5 is a main part sectional view for explaining the example of the manufacturing process for the solar cell according to the first embodiment of the present invention.

FIG. 2-6 is a main part sectional view for explaining the example of the manufacturing process for the solar cell according to the first embodiment of the present invention.

FIG. 2-7 is a main part sectional view for explaining the example of the manufacturing process for the solar cell according to the first embodiment of the present invention.

FIG. 2-8 is a main part sectional view for explaining the example of the manufacturing process for the solar cell according to the first embodiment of the present invention.

FIG. 2-9 is a main part sectional view for explaining the example of the manufacturing process for the solar cell according to the first embodiment of the present invention.

FIG. 3 is a main part perspective view of the schematic configuration of the solar cell according to the first embodiment of the present invention.

FIG. 4 is a diagram of a surface photograph of a solar cell manufactured by a manufacturing method for a solar cell according to the first embodiment of the present invention.

FIG. 5 is a diagram of a surface photograph of a solar cell manufactured by a conventional process not through a steam oxidation step.

FIG. 6 is a main part perspective view of the schematic configuration of an HE cell of a sample.

FIG. 7-1 is a characteristic chart of a change in internal quantum efficiency due to the presence or absence of oxide film removal after steam oxidation in an HE cell manufactured by carrying out the steam oxidation.

FIG. 7-2 is an enlarged view of a region A in FIG. 7-1.

FIG. 8 is a flowchart for explaining an example of a manufacturing process for a solar cell according to a second embodiment of the present invention.

### DESCRIPTION OF EMBODIMENTS

Embodiments of a solar cell, a manufacturing method for a solar cell, and a solar cell module according to the present invention are explained in detail below with reference to the drawings. Note that the present invention is not limited by the following description and can be changed as appropriate in a range not departing from the spirit of the present invention. In the drawings referred to below, for ease of understanding, the scale of components is sometimes different from the actuality. This holds true for the relationships between the drawings too. Even on a plane, hatching is applied to clearly show the drawings.

### First Embodiment

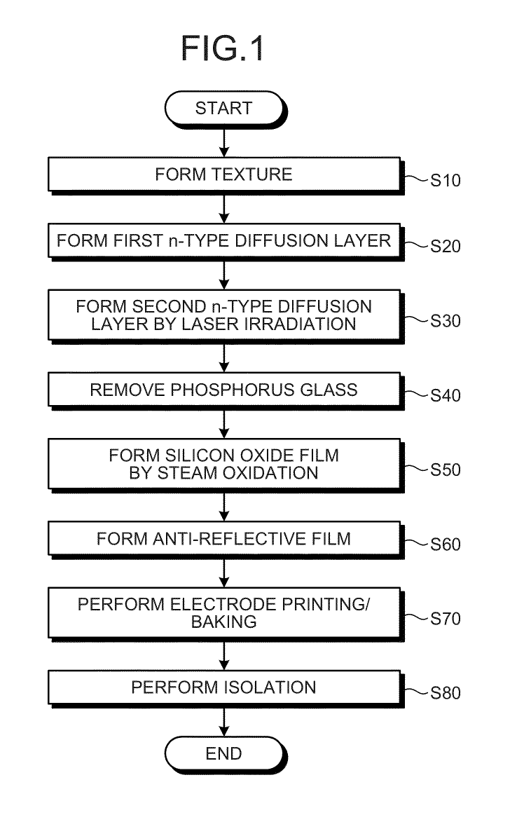

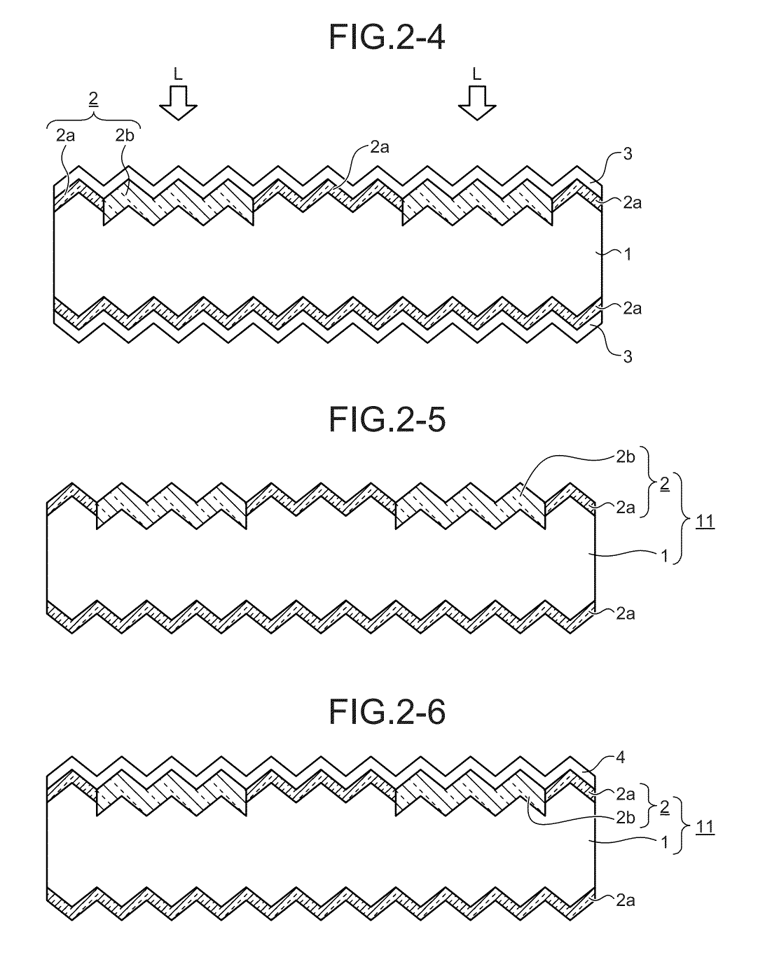

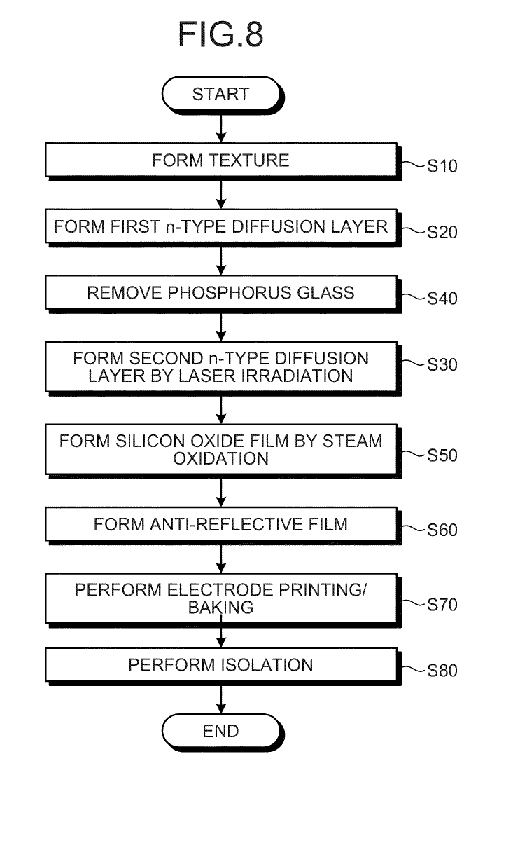

FIG. 1 is a flowchart for explaining an example of a manufacturing process for a solar cell according to the first embodiment of the present invention. FIG. 2-1 to FIG. 2-9 are main part sectional views for explaining the example of the manufacturing process for the solar cell according to the first embodiment of the present invention. FIG. 3 is a main part perspective view of the schematic configuration of the solar cell according to the first embodiment manufactured by a manufacturing method for a solar cell according to the first embodiment. Note that, although not described in FIG. 1 and the following explanation, wafer cleaning treatment, immersion treatment in hydrofluoric acid for the purpose of natural oxide film removal, and water cleaning treatment are performed between respective steps when necessary.

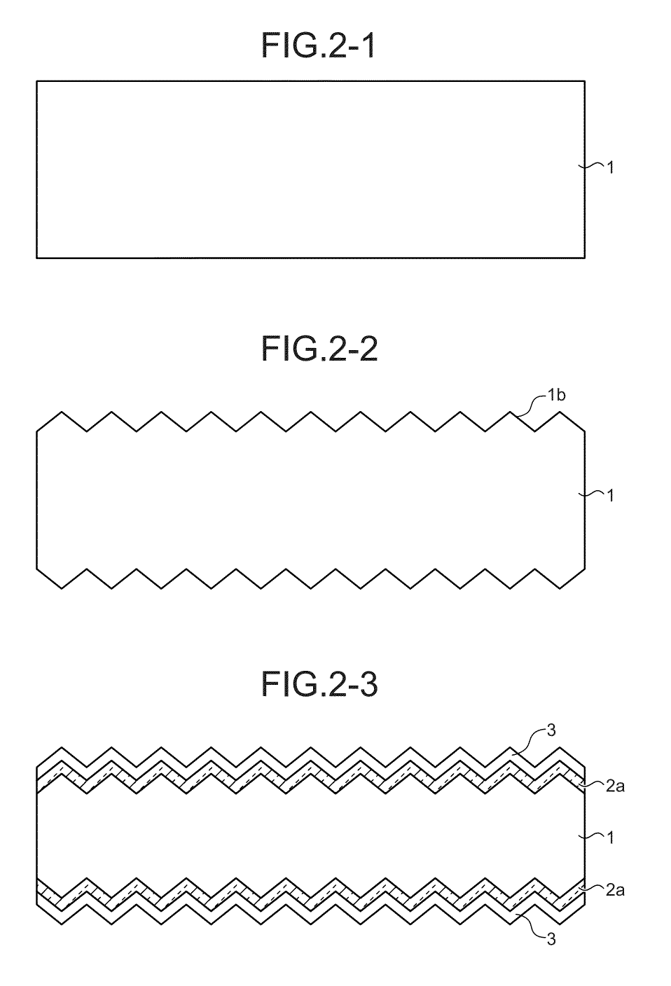

First, as a semiconductor substrate, for example, a p-type single-crystal silicon substrate (hereinafter referred to as p-type silicon substrate) 1 most often used for a consumer solar cell is prepared (FIG. 2-1).

The p-type silicon substrate 1 is manufactured by cutting and slicing a single-crystal silicon ingot or a polycrystalline silicon ingot, which is formed by cooling and solidifying molten silicon, into desired size and thickness with a wire saw using a handsaw, a multi-wire saw, or the like. Therefore, damage during slicing remains on the surface of the p-type silicon substrate 1. Therefore, first, to also serve for removal of this damage layer, the p-type silicon substrate 1 is immersed in acid or a heated alkali solution, for example, an aqueous sodium hydroxide solution or an aqueous potassium hydroxide solution to etch the surface of the p-type silicon substrate 1 to thereby remove the damaged area generated during slicing of the silicon substrate and present near the surface of the p-type silicon substrate 1 (FIG. 2-1). The p-type silicon substrate is explained as an example. However, the silicon substrate can be either a p-type or an n-type.

Simultaneously with the damage removal or following the damage removal, micro unevenness is formed as a texture structure on the surface on a light receiving surface side of the p-type silicon substrate 1 (FIG. 2-2, step S10). For example, anisotropic etching of the p-type silicon substrate 1 is performed with a solution of approximately 80° C. to 90° C. obtained by adding several to several tens of wt % of isopropyl alcohol (IPA) to several wt % of an aqueous potassium hydroxide (KOH) solution to form pyramid-like micro unevenness (texture) 1b on the surface on the light receiving surface side of the p-type silicon substrate 1. By forming such a texture structure on the light receiving surface side of the semiconductor substrate, it is possible to cause multiple reflection of light on the surface of a solar cell and efficiently absorb light incident on the solar cell into the silicon substrate. Therefore, it is possible to effectively reduce the reflectance and improve the conversion efficiency. In general, a texture structure having a random pyramid shape can be formed by anisotropic etching of the surface of the p-type silicon substrate 1 performed using alkali.

Note that, in the manufacturing method for the solar cell according to the present embodiment, a formation method for and a shape of a texture structure are not particularly limited. Any method can be used such as a method of using an alkali solution containing isopropyl alcohol and acid etching by a liquid mixture of mainly hydrofluoric acid and nitric acid, a method of forming a mask material partially provided with an opening on the surface of the p-type silicon substrate 1 and obtaining a honeycomb structure or an inverted pyramid structure on the surface of the p-type silicon substrate with etching via the mask material, or a method using Reactive Ion Etching (RIE).

Subsequently, the p-type silicon substrate 1 is put in a thermal diffusion furnace and heated under an atmosphere of phosphorus (P), which is n-type impurities. According to this step, phosphorus (P) is diffused at low concentration in the surface of the p-type silicon substrate 1 and thus a first n-type impurity diffusion layer (hereinafter referred to as first n-type diffusion layer) 2a, which is a low-concentration impurity diffusion region containing phosphorus (P) at a first concentration, is formed, thereby forming a semiconductor p-n junction (FIG. 2-3 and step S20). In the present embodiment, the first n-type diffusion layer 2a is formed by heating the p-type silicon substrate 1 at a temperature of, for example, 850° C. to 900° C. in a phosphorus oxychloride (POCl₃) gas atmosphere. Heating treatment is controlled by adjusting a treatment temperature, a treatment time, and a gas flow rate such that the surface sheet resistance of the first n-type diffusion layer 2a is, for example, approximately 80 Ω/sq.

A phosphorus glass layer (a doping glass layer) 3, which is an oxide film containing an oxide of phosphorus (P) as a main component, is formed on the surface after the formation of the first n-type diffusion layer 2a. In the present embodiment, the next step is carried out without removing the phosphorus glass layer 3. Note that, here, an example is explained in which phosphorus (P) is diffused in the p-type silicon substrate as a donor to form an n-type diffusion layer. However, when an n-type silicon substrate is used, an acceptor such as boron (B) is used as impurities to form a p-type diffusion layer.

Subsequently, laser irradiation L is performed, according to the shape of the light-receiving-surface-side electrode, in the forming region of the light-receiving-surface-side electrode, which is a region where the light-receiving-surface-side electrode is formed later, in the first n-type diffusion layer 2a coated with the phosphorus glass layer 3. Because the first n-type diffusion layer 2a is locally heated by the laser irradiation L, phosphorus (P) diffuses from the phosphorus glass layer 3. Consequently, the first n-type diffusion layer 2a subjected to the laser irradiation L has an impurity concentration higher than the impurity concentration before the laser irradiation L. Therefore, the first n-type diffusion layer 2a transforms into a second n-type impurity diffusion layer (hereinafter referred to as second n-type diffusion layer), which is a high-concentration impurity diffusion region containing phosphorus (P) at a second concentration higher than the first concentration and reduced in resistance (FIG. 2-4 and step S30). The second n-type diffusion layer 2b is formed to a region deeper than the first n-type diffusion layer 2a.

Even if there is no change in the external appearance on the surface of the p-type silicon substrate 1 before and after the laser irradiation L, the p-type silicon substrate 1 is damaged depending on the wavelength of the laser used in the laser irradiation L. Therefore, for example, a laser having a wavelength of 532 nanometers is used and the fluence is set to 1.25 to 2.00 (J/cm²). With the laser having such wavelength and fluence, there is no concern that the surface of the p-type silicon substrate 1 is damaged.

The shape of one shot of the laser in use is set to approximately 300 μm×600 μm. This shape can be slightly changed according to a lens mounted on a laser device. For example, when a light-receiving-surface-side electrode including a grid electrode having a grid electrode width of 100 micrometers and a bus electrode having a bus electrode width of 1.5 millimeters is formed, the forming region of the grid electrode is formed with a width of 300 micrometers and the forming region of the bus electrode is formed with a width of 2.1 millimeters (600 μm×4, overlap width 100 μm) in consideration of a margin of alignment during electrode formation by printing.

Photoelectric conversion efficiency of the second n-type diffusion layer 2b, which is the high-concentration impurity diffusion region, is lower than photoelectric conversion efficiency of the first n-type diffusion layer 2a, which is the low-concentration impurity diffusion region. Therefore, the region of the second n-type diffusion layer 2b protruding from the light-receiving-surface-side electrode in the surface direction of the p-type silicon substrate 1 is preferably as small as possible. However, when the actual dimensions of the grid electrode and the bus electrode used in general, alignment accuracy of printing of the light-receiving-surface-side electrode, a margin of the alignment, and the like are taken into account, the width of the second n-type diffusion layer 2b, which is the high-concentration impurity diffusion region, is set to a minimum of approximately 100 micrometers (0.1 millimeters) and set to a maximum of approximately 4 millimeters. The minimum width of the second n-type diffusion layer 2b is restricted by the grid electrode and the maximum width of the second n-type diffusion layer 2b is restricted by the bus electrode. When the width of the grid electrode is smaller than 100 micrometers, it is likely that an increase in the resistance of the electrode or a breaking of wire occurs. When the width of the bus electrode is larger than 4 millimeters, the photoelectric conversion efficiency is deteriorated because of a decrease in a light reception area.

After the laser irradiation, the phosphorus glass layer 3 is removed using hydrofluoric acid or the like (FIG. 2-5 and step S40). By carrying out the process explained above, a selective diffusion layer 2 is formed that includes the first n-type diffusion layer 2a having an impurity concentration suitable for a light receiving section and the second n-type diffusion layer 2b having an impurity concentration suitable for an impurity diffusion layer in the lower region of the light-receiving-surface-side electrode. Consequently, a semiconductor substrate 11 is obtained in which a p-n junction is formed by the p-type silicon substrate 1 made of the p-type single-crystal silicon, which is a first conductivity type layer, and the selective diffusion layer 2, which is a second conductivity type layer and an n-type impurity diffusion layer, formed on the light receiving surface side of the p-type silicon substrate 1.

Subsequently, as a passivation film 4, a silicon oxide film is formed on the surface of the selective diffusion layer 2 by steam oxidation or pyrogenic oxidation (FIG. 2-6 and step S50). Consequently, silicon oxide films are formed with different thicknesses on the first n-type diffusion layer 2a and on the second n-type diffusion layer 2b. This is because, in the first n-type diffusion layer 2a and the second n-type diffusion layer 2b, a difference occurs in phosphorus (P) concentration in the outermost surface due to the presence or absence of the laser irradiation L. Specifically, the phosphorus (P) concentration in the outermost surface of the second n-type diffusion layer 2b subjected to the laser irradiation L is lower than the phosphorus (P) concentration in the outermost surface of the first n-type diffusion layer 2a that is not subjected to the laser irradiation L. The diffusion depth of the second n-type diffusion layer 2b is large. As a result, the thickness of the silicon oxide film formed on the second n-type diffusion layer 2b is thin by approximately 10% to 30% compared with that on the first n-type diffusion layer 2a.

Subsequently, a silicon nitride film (SiN) film (n=2.0) (hereinafter referred to as PECVD-SiN film) is formed on the passivation film 4 by a PECVD method as an anti-reflective film 5 (FIG. 2-7 and step S60). When the PECVD-SiN film, which is a film having a refractive index different from that of the silicon oxide film of the passivation film 4, is formed, a difference between the thicknesses of the silicon oxide films on the first n-type diffusion layer 2a and the second n-type diffusion layer 2b appears as a difference in an interference color. This is because the difference between the thicknesses of the silicon oxide films on the first n-type diffusion layer 2a and the second n-type diffusion layer 2b is made obvious and appears as the difference in the interference color when the PECVD-SiN film is deposited on the silicon oxide films. Consequently, it is possible to visually grasp a distinction between the regions of the first n-type diffusion layer 2a serving as the light receiving region and the second n-type diffusion layer 2b, which is the forming region of the light-receiving-surface-side electrode. The silicon oxide film of the passivation film 4 formed by the steam oxidation also has a role as part of the anti-reflective film 5.

PECVD-SiN (n=2.0) is used as the anti-reflective film 5. From an optical viewpoint, the thickness of the silicon oxide film of the passivation film 4 in the light receiving region has to be thickness equal to or smaller than 30 nanometers. When the thickness of the silicon oxide film is larger than 30 nanometers, the reflectance of the silicon oxide film is higher than the reflectance of the anti-reflective film of the PECVD-SiN layer alone irrespective of how the adjustment is performed of the thickness of the PECVD-SiN formed on the silicon oxide film. Therefore, a photocurrent decreases.

As long as the film having a refractive index different from the refractive index of the silicon oxide film of the passivation film 4 is used as the anti-reflective film 5, the difference between the silicon oxide film thicknesses appears as the interference color. Therefore, the film used as the anti-reflective film 5 is not limited to the PECVD-SiN. However, the allowable range of the thickness of the silicon oxide film on the light receiving surface changes depending on the refractive index of the anti-reflective film 5 stacked on the passivation film 4. In this case, it is necessary to determine the thickness of the silicon oxide film using an optical simulation.

Subsequently, an electrode is formed by screen printing. First, a light-receiving-surface-side electrode is manufactured (before baking). That is, after silver paste 6a, which is electrode material paste containing glass frit, is applied to the anti-reflective film 5, which is the light receiving surface of the semiconductor substrate 11, in the shape of the light-receiving-surface-side electrode by the screen printing, the silver paste 6a is dried (FIG. 2-8 and step S70). The silver paste 6a is applied, for example, in the shape of a comb shape of the light-receiving-surface-side electrode including a front silver grid electrode and a front silver bus electrode.

Subsequently, aluminum paste 9a, which is electrode material paste, is applied over the entire rear surface of the semiconductor substrate 11 by the screen printing and dried (FIG. 2-8 and step S70). The distinction between the regions of the first n-type diffusion layer 2a and the second n-type diffusion layer 2b can be visually grasped according to the interference color explained above. Therefore, it is easy to perform alignment during the electrode material paste printing.

Subsequently, the electrode paste on the front surface and the electrode paste on the rear surface of the semiconductor substrate 11 are simultaneously baked at, for example, 600° C. to 900° C. Then, on the front side of the semiconductor substrate 11, a silver material comes into contact with silicon and coagulates again while the anti-reflective film 5 is melted by a glass material included in the silver paste 6a. Consequently, as the light-receiving-surface-side electrode, for example, front silver grid electrodes 6 and front silver bus electrodes 7 are obtained in a comb shape and conduction between a light-receiving-surface-side electrode 8 and the silicon of the semiconductor substrate 11 is secured (FIG. 2-9 and step S70). Such a process is called fire-through method. Note that, in FIG. 2-9, only the front silver grid electrodes 6 are shown.

The aluminum paste 9a also reacts with the silicon of the semiconductor substrate 11 and a rear aluminum electrode 9 is obtained. In the outer layer section right under the rear aluminum electrode 9, a p+ layer (BSF (Back Surface Field)) 10 containing high-concentration impurities is formed.

Thereafter, an SE cell is obtained through isolation (p-n separation) by a laser. Note that the order in which the paste that is an electrode material is applied to the light receiving surface side and the rear surface side can be changed.

As shown in FIG. 3, in the solar cell according to the first embodiment manufactured by the method explained above, on the light receiving surface side of the p-type silicon 1, the selective diffusion layer 2 is formed that includes the first n-type diffusion layer 2a having an impurity concentration suitable for the light receiving section and the second n-type diffusion layer 2b having an impurity concentration suitable for the impurity diffusion layer in the lower region of the light-receiving-surface-side electrode and whereby the semiconductor substrate 11 including a p-n junction is formed. The passivation film 4 made of a silicon oxide film is formed on the selective diffusion layer 2 and the anti-reflective film 5 made of a silicon oxide film (SiN film) is formed on the passivation film 4.

On the light receiving surface side of the semiconductor substrate 11, a plurality of the long and thin front silver grid electrodes 6 are provided side by side. The front silver bus electrodes 7 conducting with the front silver grid electrodes 6 are provided substantially orthogonal to the front silver grid electrodes 6. The front silver grid electrodes 6 and the front silver bus electrodes 7 are electrically connected to the second n-type diffusion layer 2b in bottom surface sections thereof. The light-receiving-surface-side electrode 8, which is a first electrode and has a comb shape, is formed of the front silver grid electrodes 6 and the front silver bus electrodes 7. On the other hand, on the rear surface (a surface on the opposite side of the light receiving surface) of the semiconductor substrate 11, the rear aluminum electrode 9 made of an aluminum material is provided over the entire rear surface as a rear-surface-side electrode. The p+ layer (BSF) 10 is formed in the outer layer section right under the rear aluminum electrode 9.

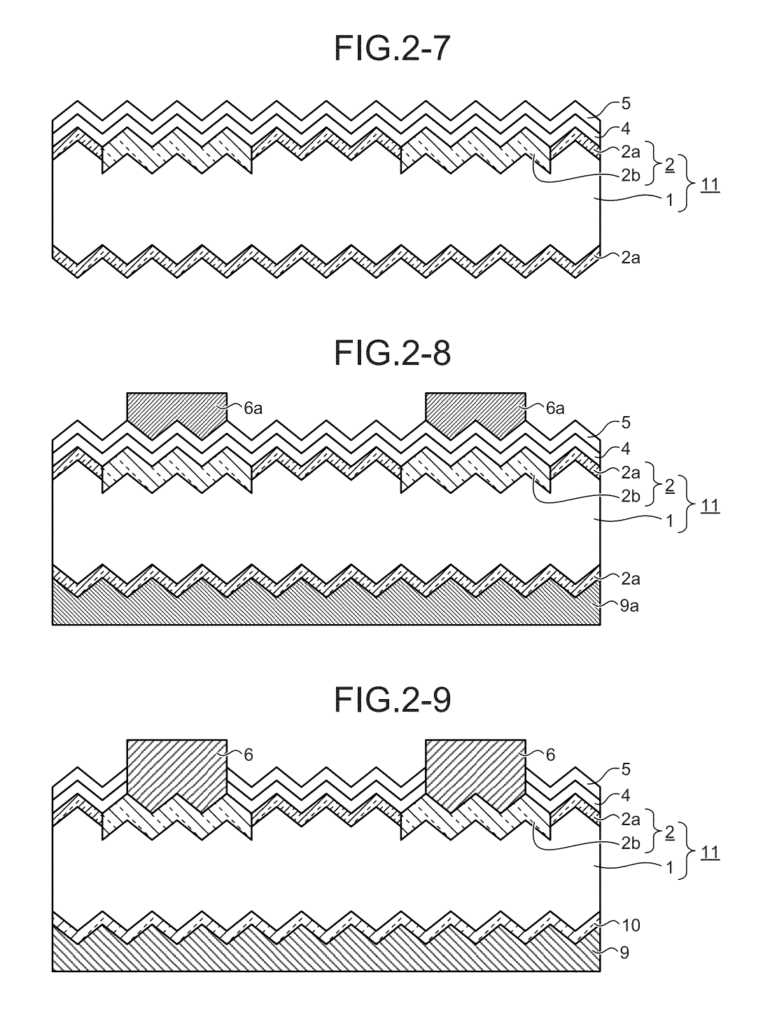

FIG. 4 is a diagram of a surface photograph of the solar cell manufactured by the manufacturing method for the solar cell according to the first embodiment. In FIG. 4, the difference between the thicknesses of the silicon oxide films on the first n-type diffusion layer 2a and the second n-type diffusion layer 2b is made obvious and appears as the difference in the interference color when the PECVD-SiN film is deposited on the silicon oxide films. Consequently, it is possible to visually grasp the distinction between the regions of the second n-type diffusion layer 2b, which is the laser irradiation region, and the first n-type diffusion layer 2a, which is a region where laser irradiation is not carried out.

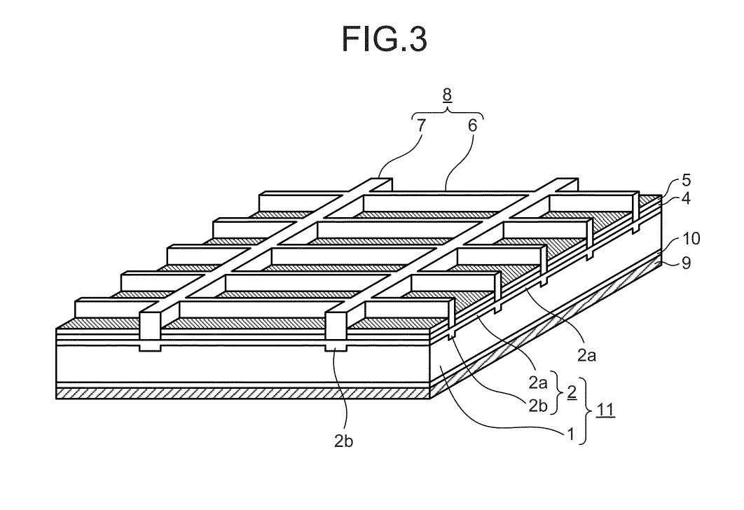

As a comparison target, a surface photograph of a solar cell manufactured by the conventional process not through the steam oxidation process as in Non Patent Literature 2 is shown in FIG. 5. FIG. 5 is a diagram showing the surface photograph of the solar cell manufactured by the conventional process not through the steam oxidation process. In FIG. 5, the distinction between the regions of the second n-type diffusion layer 2b, which is the laser irradiation region, and the first n-type diffusion layer 2a, which is the region where laser irradiation is not carried out, cannot be visually grasped well.

In this way, in the manufacturing method for the solar cell according to the first embodiment, it is possible to visualize the laser irradiation region. Consequently, for example, laser is irradiated at two or more points independently from the pattern of the forming region of the light-receiving-surface-side electrode to form an alignment region in an appropriate place in the plane of the p-type silicon substrate 1. In this region, as in the electrode forming region, the passivation film 4 having a thickness different from the thickness of the first n-type diffusion layer 2a is formed by steam oxidation or pyrogenic oxidation. Consequently, the alignment region can be used as an alignment mark when the light-receiving-surface-side electrode is formed. That is, when the light-receiving-surface-side electrode is printed, alignment only has to be performed according to the alignment region to perform electrode printing.

Note that, as a forming method for the silicon oxide film of the passivation film 4, there is dry oxidation besides the steam oxidation or the pyrogenic oxidation. However, an oxidation method that should be applied in the present embodiment is limited to the steam oxidation or the pyrogenic oxidation. Even when the silicon oxide film is formed by the dry oxidation, it is possible to provide a difference between the thicknesses of a laser irradiation section and a region in which laser is not irradiated. However, the formation rate of the silicon oxide film is low in the dry oxidation. Therefore, to form a desired thickness (e.g., 30 nanometers or less), the temperature higher than the temperature of the steam oxidation and the time longer than the time of the steam oxidation are necessary.

In the present embodiment, thermal diffusion of the p-type silicon substrate 1 is carried out in a phosphorus oxychloride (POCl₃) gas atmosphere to form the first n-type diffusion layer 2a. In this case, electrically non-active phosphorus (P) is present in the surface of the p-type silicon substrate 1. When the p-type silicon substrate 1 is processed through a high-temperature process at approximately the diffusion temperature of the phosphorus (P) in this state, the non-active phosphorus (P) is activated and already-activated phosphorus (P) is also diffused deep into the p-type silicon substrate 1; therefore, the impurity concentration profile changes. Specifically, the impurity concentration profile changes and the sheet resistance of the selective diffusion layer 2 becomes lower than the sheet resistance before the oxidation. Therefore, when the silicon oxide film of the passivation film 4 is formed by the dry oxidation, the sheet resistance of the selective diffusion layer 2 is lower than a desired setting value.

In contrast, in the steam oxidation or the pyrogenic oxidation, it is possible to form the silicon oxide film having a desired thickness at a temperature lower than the diffusion temperature of the phosphorus (P) and in a short time. Therefore, it is possible to suppress phosphorus (P) from being diffused deep into the p-type silicon substrate 1 when the silicon oxide film is formed. Further, the phosphorus (P) in the surface of the p-type silicon substrate 1 is captured into the silicon oxide film before being diffused. Therefore, it is possible to reduce the phosphorus concentration in the surface of the p-type silicon substrate 1.

The result obtained by measuring the sheet resistance of the selective diffusion layer 2 before and after oxidation when oxidation treatment is applied to the samples subjected to the processing up to step S40 is shown in Table 1. The oxidation was carried out under three conditions, i.e., the dry oxidation (850°, 30 minutes), the steam oxidation (850° C., 30 minutes), and the steam oxidation (800° C., 7 minutes). The sheet resistance was measured concerning five samples under each of the above conditions. Concerning the samples after the oxidation, the sheet resistance was measured after the formed silicon oxide film was removed by hydrofluoric acid. Thermal diffusion of phosphorus (P) during the first n-type diffusion layer 2a formation is performed at 830° C. in all the samples.

TABLE 1

| | Sheet resistance [Ω/sq] | | | | | | |
|---|---|---|---|---|---|---|---|
| | | 1 | 2 | 3 | 4 | 5 | Ave |
| Dry | Before | 72.19 | 65.68 | 64.01 | 67.99 | 64.60 | 66.89 |
| oxidation | oxidation | | | | | | |
| (850° C.-30 | After | 69.43 | 49.60 | 54.84 | 61.21 | 52.31 | 57.48 |
| min) | oxidation | | | | | | |
| Steam | Before | 71.83 | 64.91 | 64.10 | 67.04 | 63.51 | 66.28 |
| oxidation | oxidation | | | | | | |
| (850° c.-30 | After | 86.73 | 66.27 | 74.99 | 86.87 | 70.15 | 77.00 |
| min) | oxidation | | | | | | |
| Steam | Before | 64.09 | 58.75 | 59.88 | 62.59 | 57.80 | 60.62 |
| oxidation | oxidation | | | | | | |
| (850° c.-7 | After | 76.00 | 67.88 | 70.14 | 72.49 | 68.83 | 71.07 |
| min) | oxidation | | | | | | |

As it is seen from Table 1, in the samples of the dry oxidation (850° C., 30 minutes) and the steam oxidation (850° C., 30 minutes), although the samples are treated at the same temperature and in the same time, the sheet resistance of the selective diffusion layer 2 after the oxidation is lower than the sheet resistance before the oxidation in the dry oxidation. In contrast, in the steam oxidation, the sheet resistance of the selective diffusion layer 2 is higher than the sheet resistance before the oxidation. Further, in the steam oxidation, even if the temperature is lowered to 800° C. and the oxidation is performed in a shorter time, an effect that the sheet resistance is higher than the sheet resistance before the oxidation does not disappear.

Note that, when the oxidation temperature rises, the thickness of the silicon oxide film tends to be larger than the desired thickness and power consumption of a treatment apparatus increases. Therefore, the treatment temperature in the steam oxidation or the pyrogenic oxidation is considered to be appropriate up to 850° C., which is the diffusion temperature of generally-used phosphorus (P). When data of the steam oxidation is checked, it seems that an oxide film can be formed even at 600° C. However, the thickness of an oxide film that can be formed in fifty hours is approximately 30 nanometers. Therefore, the oxidation speed is extremely low. Although it depends on the target oxidation thickness, in the specifications of the present application, the temperature of approximately 800° C. is considered to be a lower limit of practical temperature. If the treatment temperature is 800° C., an oxide film having a thickness of 30 nanometers can be formed by treatment in twenty minutes. Note that the thicknesses of the oxide film at the respective temperatures are data with respect to a bare wafer. If the resistance ratio of the wafer is lower or a diffusion layer is formed on a wafer surface, the oxide film is formed thick.

Note that, according to Institute of Electrical Engineers in Japan, “Solar cell Handbook”, Institute of Electrical Engineers in Japan, 1985, p. 46, there is a description that an oxide film formed by the steam oxidation is removed by wet etching to remove a high-concentration layer (a dead layer) on the surface of the oxide film. However, unlike this description, in the technology of the present embodiment, the oxide film needs to be left without being removed. For example, in general, a PECVD-SiN film is used as an anti-reflective film of a single-crystal silicon solar cell. However, even if the phosphorus (P) concentration in the surface of the diffusion layer can be reduced by the steam oxidation and the oxide film removal, because the passivation characteristics between the PECVD-SiN film and the silicon interface are deteriorated, the reduction in the phosphorus (P) concentration in the surface of the diffusion layer is not reflected on the cell characteristics. Therefore, the oxide film needs to be left.

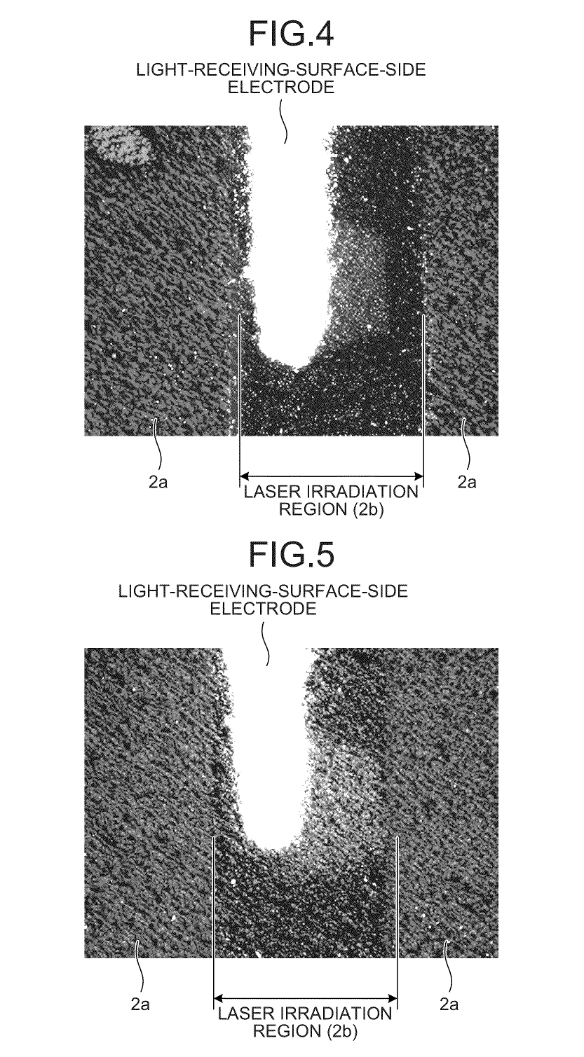

Internal quantum efficiency of the solar cell and characteristics of the solar cell due to the presence or absence of the oxide film removal after the steam oxidation in the HE cell are explained. FIG. 6 is a main part perspective view of the schematic configuration of an HE cell of a sample.

In the HE cell shown in FIG. 6, on the light receiving surface side of a semiconductor substrate 101 made of the p-type single-crystal silicon, an n-type impurity diffusion layer 102 is formed by phosphorus diffusion and a semiconductor substrate 111 including a p-n junction is formed. An anti-reflective film 103 made of a silicon nitride film (SiN film) is formed on the n-type impurity diffusion layer 102. On the light receiving surface side of the semiconductor substrate 111, a plurality of long and thin front silver grid electrodes 105 are arranged side by side, front silver bus electrodes 106 conducting with the front silver grid electrodes 105 are provided substantially orthogonal to the front silver grid electrodes 105, and the front silver grid electrodes 105 and the front silver bus electrodes 106 are electrically connected to the n-type impurity diffusion layer 102 in bottom surface sections thereof. A light-receiving-surface-side electrode 104, which is a first electrode and has a comb shape, is formed of the front silver grid electrodes 105 and the front silver bus electrodes 106. On the other hand, on the rear surface (a surface on the opposite side of the light receiving surface) of the semiconductor substrate 111, a rear aluminum electrode 107 made of an aluminum material is provided over the entire rear surface as a rear-surface-side electrode.

The HE cell was manufactured by a publicly-known method. After a silicon oxide film of 20 nanometers was formed by the steam oxidation after the n-type impurity diffusion layer 102 was formed on the light receiving surface side of the semiconductor substrate 101, the semiconductor substrate 101 was divided into two groups. In a state in which the silicon oxide film was removed in one group and the silicon oxide film is left in the other group, PECVD-SiN of the anti-reflective film 103 was formed to manufacture the HE cell. Note that, in FIG. 6, the silicon oxide film is not shown.

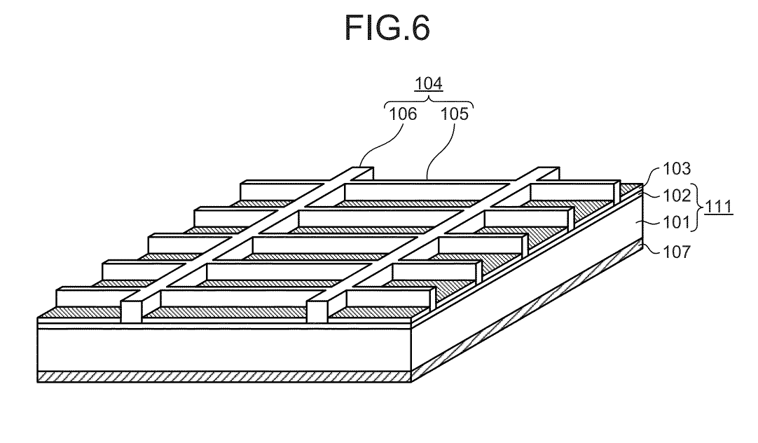

As the characteristics of the solar cell due to the presence or absence of the steam oxidation film removal in the HE cell as described above, an open-circuit voltage Voc [V], short-circuit current density Jsc [mA/cm²], fill factor (FF), and internal quantum efficiency (EFF.) [%] are shown in Table 2. FIG. 7-1 is a characteristic chart of a change in the internal quantum efficiency due to the presence or absence of the oxide film removal after the steam oxidation in the HE cell manufactured by carrying out the steam oxidation. FIG. 7-2 is an enlarged diagram of the region A in FIG. 7-1. In FIG. 7-1 and FIG. 7-2, the relation between the wavelength [nm] of light and the internal quantum efficiency is shown concerning the HE cell manufactured by removing the silicon oxide film after the steam oxidation and the HE cell manufactured in a state in which the silicon oxide film is left after the steam oxidation.

TABLE 2

| | | Jsc | | |
|---|---|---|---|---|
| | Voc [V] | [mA/cm²] | FF | Eff. [%] |
| Without | 0.6294 | 35.340 | 0.786 | 17.48 |
| oxide film | | | | |
| removal | | | | |
| With oxide | 0.6280 | 35.397 | 0.785 | 17.44 |
| film | | | | |
| removal | | | | |

As it is evident from Table 2, FIG. 7-1, and FIG. 7-2, if the silicon oxide film is removed after the steam oxidation, the open-circuit voltage (Voc) in the HE cell and the internal quantum efficiency with respect to light in a short wavelength are also deteriorated. Therefore, to realize satisfactory characteristics, the silicon oxide film has to be left on the HE cell surface. The same applies to the SE cell.

Note that a reduction in the phosphorus (P) concentration in the uppermost surface of the diffusion layer can be realized by a change in a diffusion condition (an increase in the sheet resistance of the diffusion layer) even if the steam oxidation is not used. Actually, in Non Patent Literature 2, a steam oxidation process is not performed. Therefore, if the phosphorus (P) concentration in the uppermost surface of the diffusion layer is reduced simply by an increase in the sheet resistance of the diffusion layer and alignment with the light-receiving-surface-side electrode is performed by another method, one process that is the steam oxidation can be omitted. A reduction in costs is considered to be realizable. However, this method is ineffective. This is because, when it is attempted to reduce the surface recombination speed through a reduction in the phosphorus (P) concentration in the uppermost surface of the diffusion layer in the SE cell and obtain a characteristic improvement effect of the open-circuit voltage Voc, this can be realized at a lower sheet resistance when the steam oxidation is used than when the sheet resistance of the diffusion layer is simply increased.

Table 3 shows a difference (ΔVoc=Voc(SE)−Voc(HE)) between the open-circuit voltages Voc [mV] of the HE cell and the SE cell due to the presence or absence of implementation of the steam oxidation. Voc(SE) indicates the open-circuit voltage of the SE cell, Voc(HE) indicates the open-circuit voltage Voc of the HE cell, and ΔVoc indicates a difference between Voc(SE) and Voc(HE). For a reduction in the surface recombination speed due to a reduction of the phosphorus (P) concentration in the uppermost surface of the diffusion layer, the characteristic improvement effect by the SE structure is described to be specialized for the open-circuit voltage Voc.

TABLE 3

| | Sheet resistance | ΔVoc = Voc(SE) − |
|---|---|---|
| | [Ω/sq.] | Voc(HE) [mV] |
| Without steam | HE (60) | 4.3 |
| oxidation | SE (120) | |
| With steam | HE (60) | 3.9 |
| oxidation | SE (before | |
| | oxidation: 76 → | |
| | after oxidation: | |
| | 90) | |

In the SE cell in which the steam oxidation is not carried out, a Voc improvement effect at 4.3 mV cannot be obtained unless the sheet resistance of the diffusion layer is increased to 120 Ω/sq. In contrast, in the SE cell in which the steam oxidation is carried out, the equivalent Voc improvement effect can be obtained when the sheet resistance of the diffusion layer is 90 Ω/sq. Therefore, it is seen that a reduction effect of the phosphorus (P) concentration in the uppermost surface of the light receiving region (the selective diffusion layer) by the steam oxidation is higher than the reduction effect obtained when the diffusion condition is simply changed and an increase in the sheet resistance of the selective diffusion layer is performed.

Because a difference in the sheet resistance of the diffusion layer appears as a difference in a resistance loss, when the steam oxidation is not carried out, a high fill factor (FF) cannot be obtained unless the number of grid electrodes is set larger than the number of grid electrodes provided when the steam oxidation is carried out. However, when the number of grid electrodes is increased, although a high fill factor (FF) can be obtained, an electric current decreases because a shading loss increases. Further, a necessary amount of paste for grid electrode formation increases. Therefore, the steam oxidation or the pyrogenic oxidation is considered to have a further benefit over a simple increase in the sheet resistance of the diffusion layer also from the viewpoint of the fill factor (FF) and the electrode material.

As explained above, in the first embodiment, there is a difference in the thickness of the silicon oxide film used as the passivation film 4 provided between the light receiving region and the electrode forming region. A material having a refractive index different from the refractive index of the silicon oxide film is deposited on the passivation film 4 to form the anti-reflective film 5. More specifically, the semiconductor substrate 11 on which the SE structure (the first n-type diffusion layer 2a serving as the light receiving region and the second n-type diffusion layer 2b, which is the forming region of the light-receiving-surface-side electrode) formed by the laser irradiation is formed is oxidized by the steam oxidation or the pyrogenic oxidation, whereby the silicon oxide film thinner than the silicon oxide film on the first n-type diffusion layer 2a is formed on the second n-type diffusion layer 2b. Further, the silicon oxide film is not removed and another material (PECVD-SiN) having a refractive index different from the refractive index of the silicon oxide film is deposited on the silicon oxide film to form the anti-reflective film 5.

According to the first embodiment, it is possible to visibly grasp the second n-type diffusion layer 2b, which is the forming region of the light-receiving-surface-side electrode. Therefore, it is easy to align the electrode with the forming region of the light-receiving-surface-side electrode during printing of the electrode.

According to the first embodiment, the diffusion layer having an impurity concentration equivalent to the impurity concentration of the outermost surface of the diffusion layer formed by the simple change of the diffusion condition can be realized at a lower sheet resistance. Therefore, it is possible to reduce a resistance loss in the diffusion layer and realize a solar cell having high photoelectric conversion efficiency. That is, according to the first embodiment, a reduction effect of the phosphorus (P) concentration in the outermost surface of the light receiving region is higher than the reduction effect obtained when an increase in sheet resistance of the diffusion layer is performed by simply changing the diffusion condition and an equivalent improvement effect can be obtained at lower sheet resistance. Therefore, the fill factor (FF) is less easily adversely affected.

In the first embodiment, the silicon oxide film formed by the steam oxidation is used as part of the anti-reflective film 5. Therefore, it is possible to reduce the material of the anti-reflective film 5 (PECVD-SiN) deposited on the silicon oxide film.

Therefore, according to the first embodiment, it is possible to visually clarify a distinction between the regions of the first n-type diffusion layer 2a serving as the light receiving region and the second n-type diffusion layer 2b, which is the forming region of the light-receiving-surface-side electrode, to make it easy to align the electrode. Further, it is possible to improve the characteristics of the solar cell by reducing the phosphorus concentration of the light receiving region. Consequently, it is possible to realize a solar cell with a simple electrode formation and excellent photoelectric conversion characteristics.

### Second Embodiment

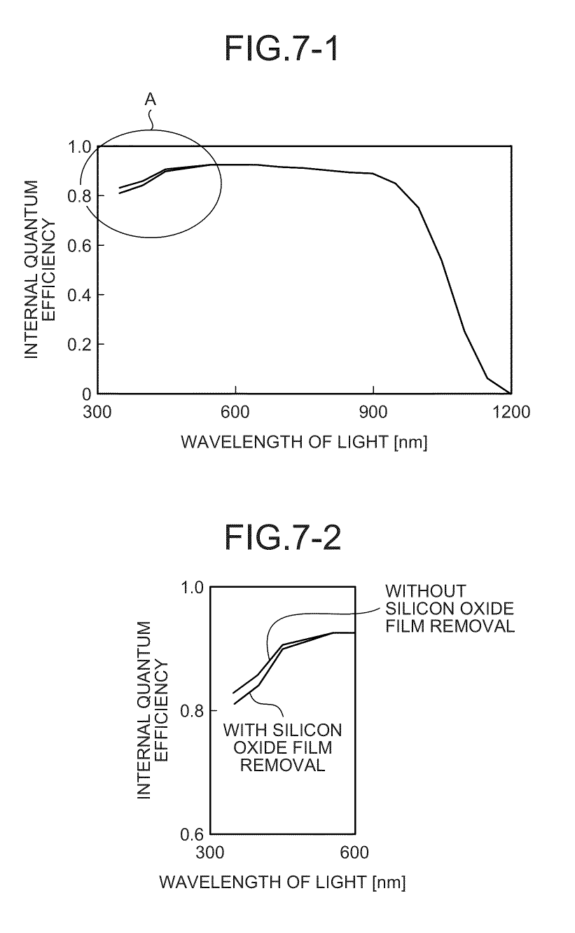

FIG. 8 is a flowchart for explaining an example of a manufacturing process for a solar cell according to a second embodiment of the present invention. In the explanation in the first embodiment, the phosphorus glass is removed after the laser irradiation. However, the order in which the laser irradiation and the removal of the phosphorus glass are performed is not limited to this. The order in which the laser irradiation and the removal of the phosphorus glass are performed can be reversed. That is, the laser irradiation can be performed after the phosphorus glass is removed.

After the thermal diffusion performed using the phosphorus oxychloride (POCl₃) gas, electrically non-activated (inactive) phosphorus (P) is present on the surface of the silicon substrate. When the laser irradiation is performed in this state, the inactive phosphorus (P) is activated by the laser irradiation, already-activated phosphorus (P) is diffused to a deeper region of the silicon substrate, and an SE structure is formed. Thereafter, if the steam oxidation or the pyrogenic oxidation is applied to the silicon substrate, it is possible to reduce the phosphorus (P) concentration in the outermost surface of the light receiving region while providing a difference between the oxidation film thicknesses of the laser irradiating section and the light receiving region. As in the first embodiment, it is possible to manufacture a solar cell of the SE structure having high photoelectric conversion efficiency.

According to the second embodiment explained above, as in the first embodiment, it is possible to visually clarify a distinction between the regions of the first n-type diffusion layer 2a serving as the light receiving region and the second n-type diffusion layer 2b, which is the forming region of the light-receiving-surface-side electrode, to make it easy to align the electrode. Further, it is possible to improve the characteristics of the solar cell by reducing the phosphorus concentration of the light receiving region of the diffusion layer. Consequently, it is possible to realize a solar cell with a simple electrode formation and excellent photoelectric conversion characteristics.

A plurality of the solar cells including the configuration explained in the embodiments are formed and the solar cells adjacent to each other are electrically connected in series or in parallel. Consequently, it is possible to realize, with a simple method, a solar cell module excellent in photoelectric conversion efficiency including a selective emitter structure. In this case, for example, the light-receiving-surface-side electrode of one of the adjacent solar cells and the rear-surface-side electrode of the other of the adjacent solar cells only have to be electrically connected.

### INDUSTRIAL APPLICABILITY

As explained above, the solar cell according to the present invention is useful for realization of a solar cell including the selective emitter structure with a simple electrode formation and excellent photoelectric conversion characteristics.

### REFERENCE SIGNS LIST

1 p-type single-crystal silicon substrate (p-type silicon substrate)
2 selective diffusion layer
2a first n-type impurity diffusion layer (first n-type diffusion layer)
2b second n-type impurity diffusion layer (second n-type diffusion layer)
3 phosphorus glass layer
4 passivation film
5 anti-reflective film
6 front silver grid electrode
6a silver paste
7 front silver bus electrode
8 light-receiving-surface-side electrode
9 rear aluminum electrode
9a aluminum paste
11 semiconductor substrate
101 semiconductor substrate
102 n-type impurity diffusion layer
103 anti-reflective film
104 light-receiving-surface-side electrode
105 front silver grid electrode
106 front silver bus electrode
107 rear aluminum electrode
111 semiconductor substrate
L laser irradiation

1. A solar cell comprising:
a semiconductor substrate of a first conductivity type that includes an impurity diffusion layer, in which an impurity element of a second conductivity type is diffused, on one surface side;
a passivation film that is formed on the impurity diffusion layer and that is made of an oxide film of a material of the semiconductor substrate;
an anti-reflective film that is made of a translucent material having a refractive index different from that of the oxide film and that is formed on the passivation film;
a light-receiving-surface-side electrode that is electrically connected to the impurity diffusion layer and that is formed on one surface side of the semiconductor substrate; and
a rear-surface-side electrode that is formed on another surface side of the semiconductor substrate, wherein
the impurity diffusion layer includes a first impurity diffusion layer, which is a light receiving region and contains the impurity element at a first concentration, and a second impurity diffusion layer, which is a lower region of the light-receiving-surface-side electrode and contains the impurity element at a second concentration higher than the first concentration,
a thickness of the passivation film on the second impurity diffusion layer is smaller than a thickness of the passivation film on the first impurity diffusion layer.

2. The solar cell according to claim 1, wherein the second impurity diffusion layer has a shape formed along a shape of the light-receiving-surface-side electrode in a plane direction of the semiconductor substrate and has a length in a lateral direction equal to or larger than 0.1 millimeters and equal to or smaller than 4 millimeters.

3. The solar cell according to claim 1, wherein the semiconductor substrate is a silicon substrate.

4. A manufacturing method for a solar cell comprising:
a first step of forming, with a thermal diffusion method, on one surface side of a semiconductor substrate of a first conductivity type, a first impurity diffusion layer, in which an impurity element of a second conductivity type is diffused at a first concentration, and an impurity element oxide film that contains an oxide of the impurity element of the second conductivity type as a main component and covers the first impurity diffusion layer;
a second step of selectively forming a second impurity diffusion layer, containing the impurity element at a second concentration higher than the first concentration, by performing laser irradiation in a forming region of a light-receiving-surface-side electrode in the first impurity diffusion layer and locally heating the forming region;
a third step of forming a passivation film, which is made of an oxide film of a material of the semiconductor substrate, with different thicknesses on the first impurity diffusion layer and the second impurity diffusion layer by oxidizing one surface side of the semiconductor substrate with steam oxidation or pyrogenic oxidation;
a fourth step of forming the light-receiving-surface-side electrode in a region on the second impurity diffusion layer on the passivation film; and
a fifth step of forming a rear-surface-side electrode on another surface side of the semiconductor substrate.

5. The manufacturing method for a solar cell according to claim 4, wherein a treatment temperature during the steam oxidation or the pyrogenic oxidation is equal to or lower than 850° C.

6. The manufacturing method for a solar cell according to claim 5, wherein
after the first step, the second step is performed without removing the impurity element oxide film, and
after the second step, the impurity element oxide film is removed.

7. The manufacturing method for a solar cell according to claim 5, wherein, after the first step, the second step is performed after the impurity element oxide film is removed.

8. The manufacturing method for a solar cell according to claim 4, wherein
the second step includes forming an alignment region by performing laser irradiation in at least two or more regions in the first impurity diffusion layer and locally heating the regions,
the third step includes forming the passivation film having a thickness different from that on the first impurity diffusion layer on the alignment region, and
the fourth step includes forming the light-receiving-surface-side electrode by performing alignment using the alignment region.

9. The manufacturing method for a solar cell according to claim 8, wherein the semiconductor substrate is a silicon substrate.

10. A solar cell module formed by electrically connecting at least two or more of the solar cells according to claim 1 in series or in parallel.

11. The solar cell according to claim 3, wherein surfaces of the first impurity diffusion layer and the second impurity diffusion layer are formed in a uniform surface state.

12. The solar cell according to claim 11, wherein the surface state is a texture structure.

13. The manufacturing method for a solar cell according to claim 4, wherein
after the first step, the second step is performed without removing the impurity element oxide film, and
after the second step, the impurity element oxide film is removed.

14. The manufacturing method for a solar cell according to claim 4, wherein, after the first step, the second step is performed after the impurity element oxide film is removed.

15. The manufacturing method for a solar cell according to claim 4, wherein the semiconductor substrate is a silicon substrate.

16. A solar cell module formed by electrically connecting at least two or more of the solar cells according to claim 2 in series or in parallel.
